(19) United States
(12) Patent Application Publication
(10) Pub. No.: US 2026/0202460 A1
(43) Pub. Date: Jul. 16, 2026

(54) METHOD FOR DEGRADATION DIAGNOSIS, CONTROLLER AND POWER ELECTRONIC MODULE

(71) Applicant: Rheinisch-Westfälische Technische Hochschule (RWTH) Aachen, Aachen (DE)

(72) Inventors: Isabel AUSTRUP, Aachen (DE); Sven KALKER, Aachen (DE); Rik W. DE DONCKER, Aachen (DE)

(73) Assignee: Rheinisch-Westfälische Technische Hochschule (RWTH) Aachen, Aachen (DE)

(21) Appl. No.: 19/131,547

(22) PCT Filed: Nov. 7, 2023
(86) PCT No.: PCT/EP2023/080939

§ 371 Date: May 21, 2025

(30) Foreign Application Priority Data
Nov. 29, 2022 (DE) 102022131588.6

(51) Int. Cl. G01R 31/27

(52) U.S. Cl. CPC G01R 31/27

(57) ABSTRACT

A method for degradation diagnosis of a power electronic module (2) having a semiconductor device (3), the method comprising: providing an input signal of the power electronic module (2) including a large signal component provided for switching on the semiconductor device (3); recording an output signal of the power electronic module based on the input signal to enable degradation diagnosis of the power electronic module (2); and the input signal includes a periodic signal component.

### TECHNICAL FIELD

The invention relates to a method with the features of the generic term of claim 1 as well as to a controller and a power electronic module.

The following background is merely intended to provide information necessary to understand the context of the inventive ideas and concepts disclosed herein. Therefore, this background section may include patentable subject-matter and should not be considered prior art per se.

### BACKGROUND

Power electronics are used in many applications, such as the distribution of electrical energy or electromobility. However, the failure of power electronic module components, such as a power converter, is one of the most common causes of failure in modern systems, such as wind turbines or photovoltaic systems. These faults can be attributed to defects in the assembly and connection technology of the power electronic module or to ageing of the semiconductor device itself. In order to ensure high reliability in such applications without costly oversizing of power electronic components, reliable information about the ageing condition of the power electronic module is necessary. This enables safe operation of the power electronic module over an extended period of time until critical ageing is reached and predictive maintenance is triggered.

The invention is based on the problem of creating a simpler degradation diagnosis with less effort.

### SUMMARY

The purpose of this summary is to present a selection of features and concepts of the invention, which are explained further below in the description. This summary is not intended to identify important or essential features of the claimed subject-matter, nor is it intended to limit the scope of the claimed subject-matter.

According to the invention, the above problem is solved by the features of the independent claims.

Specifically, the problem is solved by a method for degradation diagnosis of a power electronic module. The power electronic module has a semiconductor device. The method comprises providing an input signal of the power electronic module. The input signal has a large signal component. The large signal component is provided for switching on the power electronic module, preferably the semiconductor device. The method comprises recording an output signal of the power electronic module, preferably of the semiconductor device. The output signal of the power electronic module is based on the input signal. By recording the output signal, a degradation diagnosis of the power electronic module is enabled. Further, the input signal includes a periodic signal component.

The invention has the advantage that the prerequisites are created for carrying out degradation detection or degradation diagnosis in a power electronic module with power electronic components, such as a semiconductor device, in a simpler and more cost-effective manner. This makes localization possible so that the ageing condition of individual components of the power electronic module can be determined.

For example, the large signal component of the input signal can be a DC signal, corresponding to a DC voltage or a DC current. The periodic signal component can be a periodic small signal component. The periodic signal component may be a rectangular or sinusoidal signal component, preferably a small signal component. The periodic signal component of the input signal may be an AC signal, corresponding to an AC voltage or an AC current. The input signal can essentially consist of the large signal component and the periodic signal component. An amount of the large signal component may greater than 2.5 times (or 5 times or 7.5 times) an amplitude of the periodic signal component. The magnitude of the large signal component may less than 25 times (or 20 times or 15 times) the amplitude of the periodic signal component. For example, the large signal component may in a range of 7.5 times to 12.5 times the amplitude of the periodic signal component.

In one example, the large signal component may have a voltage in a range of 5V to 15V (or 7.5V to 12.5V). The input signal may have a voltage in a range from 3V to 17V (or 5V to 15V). The output signal may be a voltage signal shifted in time with respect to the input signal. An amplitude of the output signal may be greater than an amplitude of the input signal, for example deviating by up to 2V (or 1V or 0.5V).

The power electronic module can be a circuit designed for high power or high voltage/high current, such as a rectifier, inverter, DC converter, AC converter or switched-mode power supply. The power electronic module can be adapted to convert electrical energy. For example, the power electronic module can be used as a converter or frequency converter, for example in the field of electrical drive technology, solar inverters and converters for wind turbines for feeding regeneratively generated energy into the grid or switched-mode power supply units.

The semiconductor device can have a diac, bipolar power transistor, power MOSFET, thyristor, GTO thyristor, IGC thyristor, MC thyristor, IGBT, triac or diodes for rectification or free-wheeling diodes.

The power electronics module, preferably the semiconductor device, can change the input signal in such a way that an output signal different from the input signal is produced with a changed large signal component and/or periodic signal component.

The periodic signal component can be a continuous periodic, for example sinusoidal or rectangular, signal. The periodic signal component can be specified by input phase information and associated input frequency information. Thus, the periodic signal component can be a function of input phase information and associated input frequency information. Likewise, the output signal may include output phase information and associated output frequency information. The input frequency information can be essentially the same as the output frequency information, in particular a frequency information. In particular, output phase information and input phase information can represent a phase response in relation to the frequency information. For example, a degradation diagnosis can be made from the output phase information and the input phase information with associated frequency information, in particular by evaluating the phase response. An amplitude response from the output signal and input signal, in particular amplitude of the output signal and amplitude of the periodic signal component, can be neglected here. The output phase information, preferably frequency-resolved with associated frequency information, can be compared with a target output phase information in order to make the degradation diagnosis. The target output phase information can be based on a target output signal, which is obtained by providing a target input signal to a reference power electronic module. Here, the target input signal can correspond to the input signal or at least include the same periodic signal component.

Advantageous embodiments of the invention are indicated in the sub-claims.

The periodic signal component can be a chirp. The chirp can be provided by changing the frequency of the periodic signal component over time.

This allows a frequency-adjusted measurement to be carried out to check various components of the power electronic module for degradation in one run.

The chirp can have a frequency range between 0.1 mHz and 100 Hz. For example, the chirp may have a frequency greater than 0.1 mHz (or 0.5 mHz or 1 mHz). For example, the chirp may have a frequency of less than 100 Hz (or 10 Hz or 1 Hz).

This allows the chirp to be adjusted according to the components in order to perform a degradation diagnosis.

The large signal component of the input signal can ensure a switch-on state of the semiconductor device over the duration of the chirp. The large signal component can thus ensure that the semiconductor device is switched on as long as the chirp is fed into or modulated onto the power electronic module or the semiconductor device.

This allows conduction losses to be effectively modulated onto the semiconductor device and provides a simple solution for degradation diagnosis.

The input signal can be provided at a control terminal of the semiconductor device. In this case, an input current can be impressed into the control terminal or an input voltage connected at least to the control terminal, for example the input voltage between the control terminal and a source terminal of the semiconductor element, can be provided. The output signal can be recorded at a drain terminal of the semiconductor device. In this case, an output current can be recorded in the drain terminal or from the drain terminal to the source terminal (or vice versa) or an output voltage that is at least connected to the drain terminal, for example the output voltage between the drain terminal and the source terminal of the semiconductor element, can be recorded.

This enables a cost-effective and simple implementation in the field.

The terms control terminal, drain terminal and source terminal can be gate, drain and source or base, collector and emitter, corresponding to the technology of the semiconductor device. However, no specific technology is explicitly referred to here.

The method may further comprise determining a degradation of one or more components. The one or more components may be related to the power electronic module. Preferably, the one or more components are part or themselves components of the power electronic module. The determining may be performed by frequency-resolved comparison, preferably within the frequency range, of a phase of the output signal with a phase of the input signal. The phase of the input signal can correspond to the phase of the periodic signal component of the input signal.

The degradation of the plurality of components associated with the power electronic module may be determined by phase differences between the output signal and the input signal in corresponding frequency subranges associable with the plurality of components associated with the power electronic module, preferably within the frequency range. The frequency subranges may differ from component to component of the components associated with the power electronic module.

Put simply, the power electronic module in operation may have a phase response (between the output signal and the input signal). The phase response during operation, which results from the output signal recorded and the input signal provided, may be referred to here as the operating phase response. The operating phase response of the power electronic module may differ from a target phase response of the power electronic module, e.g. in a state before commissioning of the power electronic module. By comparing the operating phase response and the target phase response, for example by comparing curves between the operating phase response and the target phase response, the degradation of (individual) components of the power electronic module can be determined. For example, a degradation of a component associated with a predetermined frequency sub-range may be present if a difference between the operating phase response and the target phase response in the predetermined frequency sub-range of the frequency range exceeds a threshold value, for example 0.1° or 0.25°. The frequency sub-range may be less than 0.2 times (or 0.1 times) the bandwidth of the frequency range. For example, predetermined different frequency subranges of the frequency range may be associated with the components of the power electronic module. If the difference between the operating phase response and the target phase response in one or more of the predetermined frequency subranges exceeds the threshold, degradation may be present in the components associated with the one or more frequency subranges.

The above problem is also solved by a computer program. The computer program comprises instructions which, when the computer program is executed by a computer or by a controller), cause the computer or the controller to perform the method described above or at least one of the steps thereof. The computer program may be, for example, a module for starting/operating the power electronic module as described herein.

The above problem is also solved by a data carrier. The computer program can be stored on the machine-, processor- or computer-readable data carrier, for example on a permanent or rewritable storage medium. This also includes that the computer program can be provided on a server or a cloud server for downloading, for example via a data network such as the Internet or a communication connection such as a wireless connection.

The above problem is also solved by a controller. The controller is used for degradation diagnosis of a power electronic module with a semiconductor device. The controller is adapted to provide an input signal of the power electronic module, preferably of the semiconductor device, which includes a large signal component provided for switching on the semiconductor device. The controller is adapted to record an output signal of the power electronic module, preferably of the semiconductor device, based on the input signal in order to enable a degradation diagnosis of the power electronic module. The input signal includes a periodic signal component, for example a sinusoidal or rectangular small signal component.

The controller can be performed as a module and thus be integrated into or attached to the power electronic module. This can result in simple implementation options that are also cost-effective.

The controller may be adapted to adapt a power to be delivered to the semiconductor device based on a result of the degradation diagnosis, which is performed based on a comparison of the output signal to the input signal.

The above problem is also solved by a power electronic module. The power electronic module has a semiconductor device. The power electronic module is adapted to receive an input signal of the power electronic module, preferably of the semiconductor device, which includes a large signal component provided for switching on the semiconductor device. The power electronic module is adapted to transmit an output signal of the power electronic module, preferably of the semiconductor device, based on the input signal in order to enable a degradation diagnosis of the power electronic module. The input signal includes a periodic signal component, for example a sinusoidal or rectangular small signal component.

The power electronic module can have components such as a carrier, a substrate for thermally connecting the semiconductor device to the carrier and a heat sink. The semiconductor device can be connected to the substrate via a soldered connection. The heat sink can be connected to the carrier via a thermally conductive layer. The controller may be adapted to perform the degradation diagnosis of at least one of the components of the power electronic module.

The above problem can also be solved by a power electronic system. The power electronic system is used for degradation diagnosis and has a power electronic module as described above and a controller as described above.

The power electronic system can form an integral part of a motor vehicle, a photovoltaic system or a wind turbine.

Thus, a complete system as well as modular components can be provided, enabling a more cost-efficient implementation of degradation diagnosis without having to resort to temperature sensors.

In other words, the invention relates to a new method that diagnoses various degradation or aging effects in power electronic modules (including power electronic modules) in a minimally invasive manner and without the use of expensive sensors. In particular, the invention may relate to degradation diagnosis in power electronic modules by detecting the phase shift of the electrical response. Different states of degradation affect the phase of the frequency response of the thermal impedance at certain frequencies. Therefore, at these frequencies, a phase shift between semiconductor losses and junction temperature differs for different degradation/aging effects.

In order to utilize the phase shift, the semiconductor losses and the junction temperature are determined in previous methods. Precise loss calculations and temperature sensors with a high bandwidth are used for this in the previous methods. Temperature-sensitive electrical parameters (TSEPs) can be used here. However, these are usually not only dependent on the temperature, but also on the degradation, among other things. For this reason, recalibration may be necessary for different degrees of degradation in previous methods.

The method proposed here, on the other hand, can use information on the phase of the thermal impedance without determining the thermal impedance itself. This means that both temperature sensors and loss calculations can be dispensed with. For the indirect determination of the phase of the thermal impedance, periodic conduction losses with low frequency can be impressed or impacted, for example with the help of a (small) signal manipulation of the control electrode of the power semiconductor. In addition, the phase shift between the loss imprint and a temperature-dependent voltage (as TSEP), for example the forward voltage, can be measured. The phase shift can essentially result from a dynamic response of the thermal impedance, as the phase-shifted junction temperature influences the TSEP. Changes in the phase shift can therefore identify corresponding types of degradation.

In other words, (small) signal losses with different frequencies can be impressed into the semiconductor device. One possible implementation for this can be the modulation of a (small) signal excitation on the gate-source voltage of a transistor as a semiconductor device, for example a SiC MOSFET. The resulting drain-source voltage of the SiC MOSFET is also superimposed with this signal, preferably a small signal, due to the dependence of the ON-resistance on the gate-source voltage. In addition, the ON-resistance can be dependent on the temperature. The temperature reacts with a time delay to changes in conduction losses, which can be recognized by the phase of the thermal impedance. This phase shift between conduction losses and temperature response can be influenced by various ageing mechanisms, such as changes in the thermal path between the semiconductor and the heat sink. The phase-shifted temperature signal can therefore lead to a phase shift between the gate-source voltage and the drain-source voltage due to the temperature dependence of the ON-resistance of the semiconductor device. Alternatively, other voltages or currents dependent on the junction temperature of the semiconductor device under consideration can also be considered. Changes in the phase shift between the excitation signal and the temperature-dependent voltage/current at certain frequencies can indicate degradation in the power electronic module. The frequencies at which the change in phase shift occurs can enable the degradation phenomenon to be localized.

The (small) signal excitation of the gate-source voltage of a transistor as a semiconductor device can be used with Si MOSFETs, IGBTs and wide bandgap transistors such as GaN HEMTs and SiC MOSFETs. With bipolar transistors as semiconductor devices, (small) signal excitation of the base current is possible. One possible implementation can be that the periodic, for example sinusoidal or rectangular, gate-source voltage is adjusted via a digital-to-analog converter (DAC), which is controlled by a microcontroller (e.g. as part of the controller described herein). The voltage measurement of the gate-source voltage and the drain-source voltage can be performed via a high-impedance voltage tap using a respective instrumentation amplifier. The tapped voltages can be converted into digital signals by analog-to-digital converters (ADCs). Prior to this, the tapped voltages can be processed according to the requirements of the ADCs, for example using a single-Ended-To-Differential amplifier and an anti-aliasing filter. A fundamental frequency of both voltages can be determined using a Fast Fourier Transform. The phase information associated with the fundamental frequency can then be used to determine the phase shift.

In contrast to previous methods, the method presented here does not require precise loss and temperature determination, including temperature sensors, which significantly simplifies implementation in a power electronic system and makes it more cost-effective. For example, it can be used by module manufacturers to test their modules before they are sold. It can also be used for predictive maintenance of power components in hard-to-access locations, such as offshore wind turbines.

Thermomechanically induced degradation modes, such as fatigue of conduction electronic components like solder and thermal interfaces, can be identified, for example without the need to monitor changes in thermal response, and related to localized degradation modes. This eliminates the need for methods that only imprint periodic losses into the semiconductors and extract the junction temperature response using TSEPs. In particular, a magnitude of the thermal impedance and the phase changes can be correlated with the degradation mode having a peak sensitivity at the excitation frequency.

In contrast to the present invention, previous thermal impedance spectroscopy has the following disadvantages: 1) The required accurate temperature measurement is complex and expensive when performed using TSEPs, as it requires high bandwidth measurement of electrical parameters; 2) Accurate calculation or measurement of component losses is difficult to realize; and 3) Most TSEPs are affected by component degradation, requiring recalibration at different degrees of degradation.

Although some of the aspects described above relate to the method, the power electronic module or the power electronic system, these aspects may also apply to the other aspects thereof in a corresponding manner.

In one example, the power electronic system, power electronic module and/or controller may be implemented using hardware circuitry, software means or a combination thereof. For example, multiple units of the power electronic system, power electronic module and/or controller may each be implemented in a single physical unit, such as when multiple functions are implemented in software. The units of the power electronic system, power electronic module and/or controller can also be implemented in hardware components. The units of the power electronic system, power electronic module and/or controller are each to be understood as functional units that are not necessarily physically separated from one another. For example, the power electronic system, power electronic module and/or controller can be implemented at least partially as a computer, field-programmable logic array (FPLA), field-programmable gate array (FPGA), microcontroller, CPU (e.g. with multiple cores), graphics processing unit (GPU), application-specific integrated circuit (ASIC) and/or digital signal processor (DSP).

All technical and scientific terms used herein have the meaning that corresponds to the general understanding of the skilled person in the technical field of power electronics; they are to be interpreted based on the definitions to be found in the dictionary or the technical jargon relating to this technical field. If technical terms are used incorrectly here and thus do not express the technical idea of the present invention, they can be replaced by technical terms that convey a correct understanding to the skilled person.

If in the present case it is meant that a component is “connected” to another component, this can mean for the purpose of the present disclosure that these components can also be directly connected to each other. The term “directly” indicates that there is no other component in between.

The method steps described herein should not be construed herein as having to be performed in any particular order, unless expressly or implicitly indicated otherwise, for example if these method steps cannot be interchanged for technical reasons. The method steps may also be carried out directly one after the other (without further intervening steps) and/or consecutively.

### BRIEF DESCRIPTION OF THE DRAWINGS

Further objectives, features, advantages and possible applications are shown in the following description of embodiments, which are not to be understood as limiting, with reference to the associated drawings. The same or similar elements in the drawings are always marked with the same or similar reference numbers. Detailed explanations of known functions and structures are omitted insofar as they detract from the invention.

The drawings show in:

FIG. 1 a schematic representation of a power electronic system;

FIG. 2 a schematic representation of a method for degradation diagnosis;

FIG. 3 a schematic representation of a controller;

FIG. 4 a control block diagram for degradation diagnosis; and

FIG. 5 Frequency-resolved phase diagrams.

### DETAILED DESCRIPTION

The method, the power electronic system, the power electronic module and the controller will be described in relation to the embodiments. Without being limited to this, specific details are explained in order to provide a deeper understanding of the invention.

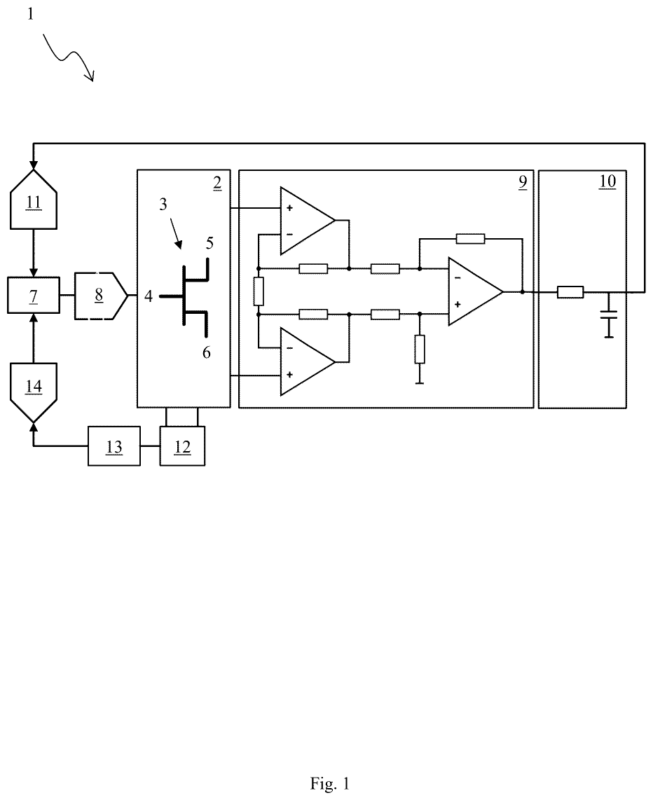

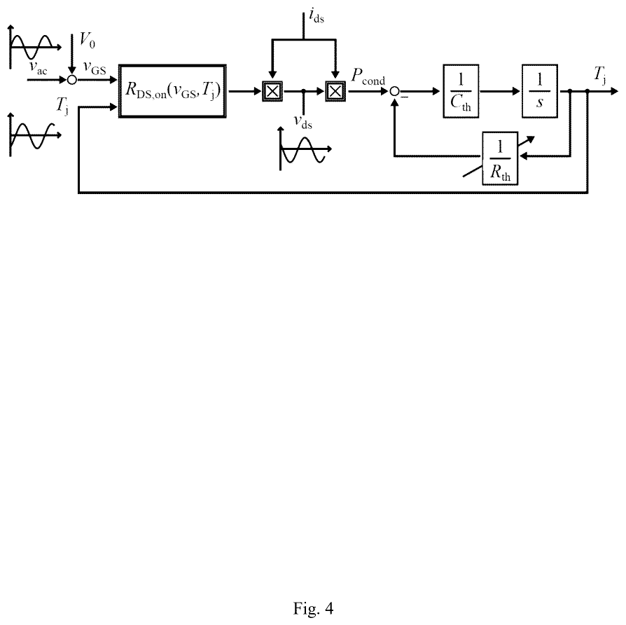

FIG. 1 shows a schematic representation of a power electronic system 1. The power electronic system 1 has a power electronic module 2 with a semiconductor device 3. The semiconductor device has a control terminal 4, drain terminal 5 and source terminal 6. In the following, it is assumed that the semiconductor device 3 is a MOSFET, for example a SiC MOSFET. Conduction losses are modulated in such a way that the gate-source voltage v_{GS} and the drain-source voltage v_{ds} are measured (see FIG. 4). The power electronic module 2 to be tested can, for example, be connected to a heat sink on the underside of the semiconductor device 3. The electrical contacts of the power electronic module 2 are connected to a circuit board of the other circuit elements 7 to 14 of the power electronic system 1. The power electronic system 1 further has a controller 7 which is used to dynamically adjust the gate-source voltage v_{GS} of the semiconductor device 3 via a digital-to-analog converter (DAC) 8, for example a 12-bit digital-to-analog converter IC.

Gate-source voltage and drain-source voltage are determined via respective measuring units 9, 10 and 12, 13 and analog-to-digital converters (ADC 11, 14). One or more of these elements 9 to 14 can also be part of the controller 7 or integrated therein. For better understanding, these are listed separately. The measuring units are divided into elements 9 and 10 or 12 and 13 in FIG. 1. Here, in the measuring unit associated with the drain-source voltage, a first instrumentation amplifier 9 is connected upstream of a first anti-aliasing filter 10, the output of which is connected to the first ADC 11. In the measuring unit associated with the gate-source voltage, a second instrumentation amplifier 12 is connected upstream of a second anti-aliasing filter 13, the output of which is connected to the second ADC 14.

As a further option, the respective measuring unit can also be divided into three parts: The voltage to be measured (gate-source or drain-source) is connected to the power electronic module 2 via an instrumentation amplifier with a high input impedance. A single-ended-to-differential amplifier with a cascaded operational amplifier can then convert the voltage into a differential signal, which can be converted into a digital signal, for example, by a 24-bit sigma-delta ADC of the controller 7 after it has been filtered by an anti-aliasing filter.

For example, in both alternatives, the voltage can be tapped via gate source and drain source with high impedance.

The controller 7 determines the gate-source voltage by adjusting the output voltage of the DAC 8, for example via Serial Peripheral Interface (SPI). This output voltage can be connected to an instrumentation amplifier, which converts the output voltage into gate-source voltages in the range from −5 V to 20 V. The modulation of the gate-source voltage is realized by generating a periodic voltage, for example sine wave voltage or square wave voltage, with a variable sampling frequency at the output of the DAC 8. The variable update frequency is selected so that the number of sampling points per period remains constant. The advantage of this method is that the values for a periodic voltage period can be stored on the controller 7 and do not have to be calculated in real time. The frequency at which the gate-source and drain-source voltage values are updated via the DAC 8 corresponds to the sampling frequency of the ADCs 11 and 14. The time- and/or frequency-resolved voltage values recorded via the ADCs 11 and 14 can be transmitted to an external computer for evaluation.

In post-processing, the fundamental frequency of the gate-source voltage v_{GS} and the drain-source voltage v_{ds} can be determined using a Fast Fourier Transform (FFT). The phase information of the fundamental frequency is then used to determine the phase shift between the gate-source voltage v_{GS} and the drain-source voltage v_{ds}.

When the method is carried out, the MOSFET can be kept permanently switched on and can conduct any drain-source current i_{(ds)}, for example around 5 A, which is only constant in special cases. A periodic, preferably sinusoidal or rectangular, (low) signal voltage v_{ac} with a variable frequency and an amplitude of 1 V is modulated onto the constant gate-source voltage V₀ of 10 V. Each frequency is applied to the gate for a half or whole period, for example a sine or square wave period. For example, an integer periodic component or an integer divisor (e.g. ½, ⅓, ¼, . . . ⅛) of the period can be used. Here, the method is not limited to a single oscillation, for example sine wave or square wave, but methods for modulation can be used in which the periodic, for example sinusoidal or rectangular, (low) signal voltage v_{ac} has several frequencies, whole or several frequency ranges within the frequency range described herein. This can reduce the time required.

The bandwidth (also known as the frequency sub-range) in which changes in thermal impedance occur provides information about the location of the ageing effects in the thermal path. The closer the ageing effect is to the device, the higher the frequency to be considered.

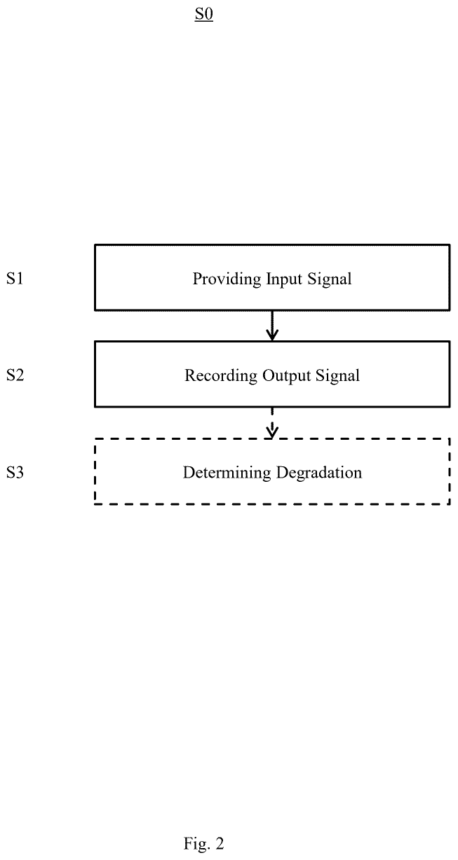

With reference to FIG. 1, FIG. 2 shows in general a schematic representation of a method S0 for degradation diagnosis of the power electronic module 2 with the semiconductor device 3. The method S0 comprises providing S1 an input signal of the power electronic module 2 including a large signal component intended to switch on the semiconductor device 3. The method S0 further comprises recording S2 an output signal of the power electronic module 2 based on the input signal to enable a degradation diagnosis of the power electronic module 2. The input signal includes a periodic, for example sinusoidal or rectangular, (small) signal component. For this purpose, the degradation of one or more components associated with the power electronic module 2 is optionally determined by frequency-resolved comparison of a phase of the output signal with a phase of the input signal.

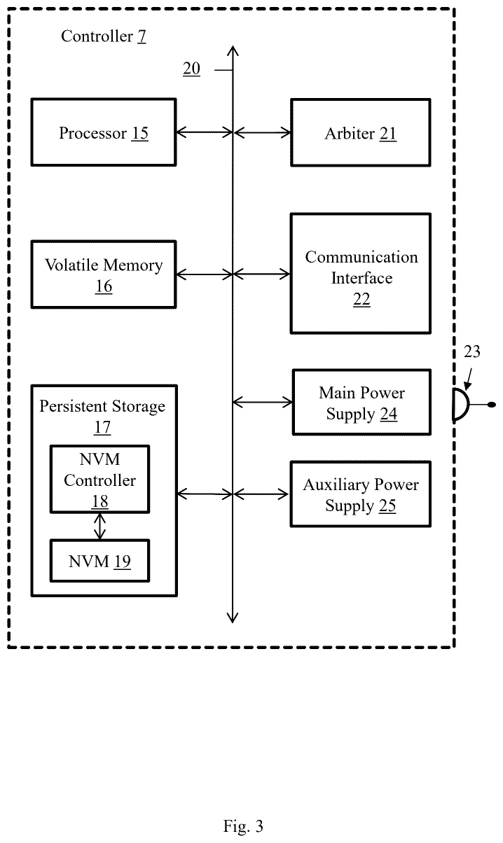

For example, the method steps shown as blocks of the block diagram in FIG. 2 may be substantially mapped in a machine-, processor- or computer-readable data carrier and thus performed by a computer or processor as described, for example, below with respect to FIG. 3. Examples may further be or relate to a computer program that includes program code for performing at least a portion of the method steps of FIG. 2, when the computer program is performed on the computer or processor. An example may also have a volatile memory or persistent storage, such as also described below with respect to FIG. 3, that is machine-, processor- or computer-readable and encodes machine-executable, processor-executable or computer-executable programs with instructions that cause some or all of the method steps to be performed.

FIG. 3 shows a schematic representation of a controller in the form of a computer. The controller 7 implements one or more steps of the method as represented in FIG. 2. In particular, the controller 7 provides functionality, such as computer software, which runs on the controller 7 and performs one or more steps of the method. In particular, the controller 7 may perform instructions related to the input signal and/or output signal included in the computer program described herein and cause the controller 7 to perform the one or more steps of the method.

It is provided herein that the controller 7 takes any suitable physical form. As an example, the controller 7 may be at least partially adapted to be an embedded computer, microcontroller, system-on-chip (SOC) and/or single board computer (SBC). The controller 7 may be unitary or distributed or may span one or more locations. The controller 7 may perform one or more steps of the method without significant spatial or temporal limitation. As an example, the controller 7 may perform one or more steps of the method in real time, in parallel or in batch mode. The controller 7 may perform step(s) of the method at different times or locations.

The controller 7 has at least one or more of the following components: a processor 15, a volatile memory 16, a persistent storage 17 with NVM controller 18 and non-volatile memory device (NVM) 19, a bus 20, an arbiter 21, a communication interface 22, a power terminal 23, a main power supply 24 and an auxiliary power supply 25. The components of the controller 7 may be performed at least partially in hardware and/or software. The interconnection of the components of the controller 7 is structured as in FIG. 3 merely for the sake of simplicity. In particular, the wiring and connection may differ in the implementation due to signal processing and signaling.

The processor 15 has means for performing instructions related to the input signal/output signal, for example, of the computer program described herein. For example, the processor 15 may load the instructions associated with the input signal/output signal included in the computer program described herein, e.g., from the volatile memory 16 and/or the persistent storage 17, and then execute the instructions, which in turn causes the processor 15 to perform the one or more steps of the method as represented, for example, in FIG. 2. The processor 15 may have an internal register/cache for the data based on the input signal/output signal, for the instructions associated with the data based on the input signal/output signal, and/or for associated addresses. The processor 15 may have an FPLA, an FPGA, a microcontroller, a CPU, a GPU, an ASIC and/or a DSP for accessing the internal register/cache. As an example, to perform the instructions associated with the input signal/output signal, the processor 15 may retrieve them from the internal register/cache of the processor 15, the volatile memory 16, or the persistent storage 17; decode and perform them; and then write a result to the internal register/cache of the processor 15, the volatile memory 16, or the persistent storage 17.

As an example, the processor 15 may have an instruction cache, a data cache and/or a translation buffer (TLB). The instructions in the instruction cache related to the input signal/output signal may be copies of instructions in the volatile memory 16 and/or persistent storage 17, and the instruction cache may accelerate retrieval of these instructions related to the input signal/output signal by the processor 15. The data in the data cache based on the input signal/output signal may be copies of data for the instructions currently executing on the processor 15 and related to the input signal/output signal in the volatile memory 16 and/or persistent storage 17. The results of the previous instructions performed on the processor 15 and related to the input signal/output signal, may be provided for access by subsequent instructions to be performed on the processor 15 and related to the input signal/output signal, or for writing to the volatile memory 16 and/or persistent storage 17. The data cache can accelerate the read or write operations of the processor 15. The addresses in the TLB related to the input signal/output signal may be address references to addresses in the volatile memory 16 and/or persistent storage 17 to accelerate virtual address translation for the processor 15.

The volatile memory 16 may be a dynamic RAM (DRAM) or a static RAM (SRAM). In particular, the volatile memory 16 may be adapted to be the data carrier described herein on which the computer program described herein may be at least temporarily stored. In addition, the volatile memory 16 may be a single or multi-channel RAM. The volatile memory 16 may have a main memory for storing instructions related to the input signal/output signal for the processor 15, which then performs these instructions; or the data based on the input signal/output signal for the processor 15 to use to operate with. As an example, the controller 7 may load these instructions into the volatile memory 16 from the persistent storage 17 or another source (such as another computer, the network, or the cloud). The processor 15 may then load these instructions from the volatile memory 16 into the internal register/cache of the processor 15. In order to perform these instructions, the processor 15 may fetch and decode these instructions from the corresponding internal register/cache. During or after performing these instructions, the processor 15 may write a result (which may be intermediate or final results) to the internal register/cache. The processor 15 may then write the result to the volatile memory 16.

For example, the processor 15 performs only the instructions related to the input signal/output signal in the internal register/cache of the processor 15 or in the volatile memory 16 (as opposed to the persistent storage 17), and operates only on the data based on the input signal/output signal in the internal register/cache of the processor 15 or in the volatile memory 16 (as opposed to the persistent storage 17). A memory management unit (MMU—not shown) may be located between the processor 15 and the volatile memory 16, and may support access requested by the processor 15 associated with the input signal/output signal to the volatile memory 16.

The volatile memory 16 may be a memory shared by the processor 15 and the communication interface 22. The communication interface 22 thereby accesses the shared volatile memory 16 via the processor 15. For example, the communication interface 22 may not include a built-in memory. Here, the communication interface 22 may share the volatile memory 16 connected to the processor 15. The processor 15 may have a memory access path that enables access to the shared volatile memory 16 associated with the input signal/output signal. The communication interface 22 accesses the shared volatile memory 16 via the memory access path of the processor 15. The communication interface 22 is enabled to access the shared volatile memory 16 in association with the input signal/output signal while the memory access path is active and the processor 15 is inactive. Here, the memory access path is active without intervention of the processor 15. The memory access path is switched off while the processor 15 and the communication interface 22 are inactive. The memory access path is turned on without intervention of the processor 15 as soon as a request to pair the memory access path with the processor 15 is received while the memory access path is turned off and the communication interface 22 is active.

The persistent storage 17 has a mass storage, for example a non-volatile memory (NVM) 19 for the data based on the input signal/output signal or the instructions related to the input signal/output signal. In particular, the persistent storage 17 may be adapted to be the data carrier described herein, on which the computer program described herein may be stored. As an example, the persistent storage 17 may be a solid state storage (SSD), a flash memory, a non-volatile memory card, a Secure Digital Memory Card (SD), an Embedded Multi Media Card (eMMC) and/or a Universal Serial Bus (USB). The persistent storage 17 may store the data based on the input signal/output signal in an erasable or non-erasable manner. The persistent storage 17 may be located in the controller 7, i.e. internally, or externally thereto. The persistent storage 17 may have the NVM controller 18 which supports the communication for passing the data based on the input signal/output signal between the processor 15 and the persistent storage 17, in particular the NVM 19 of the persistent storage 17.

The bus 20 herein can be understood as a subsystem of the controller 7, which transmits the data and/or electrical power based on the input signal/output signal between the components of the controller 7. The (one) bus 20 may connect the components of the controller 7 via the same set of wires. The bus 20 may be adapted to dedicated communication of the data based on the input signal/output signal between two or more of the components of the controller 7. The bus 20 may have a ring topology, star topology, (partially) meshed topology, bus topology, tree topology and/or line topology. The bus 20 may have one or more of the following bus types: Accelerated Graphics Port (AGP), HyperTransport (HT), Industry Standard Architecture (ISA), Peripheral Component Interconnect (PCI), PCI-Express (PCIe), Serial Advanced Technology Attachment (SATA) and/or INFINIBAND.

The bus 20 can be a system bus via which the processor 15 is connected to the other components of the controller 7. Here, the bus 20 can be synchronous—the transfer of the data based on the input signal/output signal takes place bidirectionally with a clock edge of a clocking of the bus 20—and/or asynchronous—no clocking, but a handshake takes place to transfer the data based on the input signal/output signal. In such a semi-synchronous system bus, the bus 20 is clocked, but control lines enable wait cycles in order to also use slow components such as the persistent storage 17 via the bus 20.

The arbiter 21 may be provided for at least partial control of the bus 20. The arbiter 21 can be understood as a coprocessor ancillary to the processor 15. Based on a two-way handshake or three-way handshake, the arbiter 21 controls the access to the bus 20 associated with the input signal/output signal. For this purpose, the three signals bus request (BREQ) for forwarding the data based on the input signal/output signal, bus grant (BGRT) for confirming and approving the forwarding and bus grant acknowledge (BGA) for optional forwarding feedback are used.

The arbiter 21 simultaneously receives several BREQs from different components of the controller 7 via the bus 20. The arbiter 21 sorts the BREQs according to priority and forwards them sequentially—in a pipeline—to the processor 15. As soon as the processor 15 has received the BREQ, the processor 15 sends the BGRT to the arbiter 21 or directly to the component of the controller 7 transmitting the BREQ. A lower-priority BREQ of the BREQs in the pipeline—e.g., from another component of the controller 7—is forwarded to the processor 15 in response to a BGRT sent by the processor 15 with respect to the BREQ having priority in the pipeline and related to at least a portion of the data based on the input signal/output signal. The BGRT related to the lower priority BREQ is transmitted from the processor 15 to the arbiter 21 after processing the at least a portion of the data based on the input signal/output signal. The arbiter 21 may, for example, in turn transmit to the processor 15, in response to the BGRT related to the lower-ranking BREQ, a further lower-ranking BREQ in the pipeline—which relates, for example, to another portion of the data based on the input signal/output signal—of the BREQs. Similarly, in response to each BGRT from the processor 15, the arbiter 21 may transmit a respective BGA related thereto to the processor 15. In the procedure described herein, a BGA can also be omitted altogether. This saves overhead in the communication between the components of the controller 7, i.e. a two-way handshake is provided instead of a three-way handshake.

The bus 20 can also have a data bus, address bus and control bus. In this case, the data based on the input signal/output signal is transmitted bidirectionally between the components of the controller 7 via the data bus. The address bus is operated solely by the processor 15 and transmits memory addresses related to the input signal/output signal unidirectionally. The control bus is controlled solely by the arbiter 21, e.g. in the sense of a monitor, and transfers control of it to the processor in the pipeline-like manner as described above in order to control the transmission of the data based on the input signal/output signal.

The communication interface 22 enables the controller 7 to communicate with a network, e.g. with an ad hoc network, a wireless personal area network ((W)PAN), e.g. a Bluetooth WPAN, a local area network (LAN), a WI-FI network, a WI-MAX network, a mobile radio system (e.g. 4G, 5G or 6G) and/or at least part of the Internet. In particular, the communication interface 22 can use this to forward the data based on the input signal/output signal to an evaluation unit. The communication interface 22 can also provide a direct and/or fixed connection to the evaluation unit, for example a PC.

The power terminal 23 may be arranged at a dedicated connection point on a housing of the controller 7. The power terminal 23 can represent a central power supply point for the components of the controller 7 (but also of the power electronic module 2) and connects the controller 7 or its components, preferably the main power supply 24, to an external power source (outside the controller 7). In the case of an integrated main power supply 24, the power terminal 23 can also be an integrated component of the controller 7 or the main power supply 24.

The main power supply 24 supplies at least one or more of the components of the controller 7 with electrical power, e.g. via the bus 20. In particular, the main power supply 24 charges the auxiliary power supply 25 with electrical power, for example from outside the controller 7, e.g. in the event that the main power supply 24 is connected to the power source outside the controller 7. Here, the main power supply 24 may represent a preferred component used to power the components of the controller 7 and have, for example, an accumulator or a battery. The main power supply 24 may have further components such as voltage regulators, DC voltage stabilizers, series regulators, buck converters and/or boost converters to meet the corresponding requirements of the components of the controller 7. Here, the power terminal 23 may have either a dedicated fixed power supply connection to the external power source, such as a power grid, or a detachable power supply connection for charging the accumulator or battery of the main power supply 24. To this end, the main power supply 24 may have an inverter to provide a predetermined DC power supply from an AC power source connected via the power terminal 23 as the external power source. The predetermined DC power supply may also already be provided from a DC power source connected via the power terminal 23 as the external power source. The DC power supply may be controlled by the above-mentioned voltage regulators and supplied to the components of the controller 7 as set DC power supplies.

The auxiliary power supply 25 is connected to the volatile memory 16 and/or the persistent storage 17 via the bus 20. The auxiliary power supply 25 is charged by the electrical power of the main power supply 24. The auxiliary power supply 25 may be located inside or outside the controller 7, or inside or outside the volatile memory 16 and/or the persistent storage 17. For example, the auxiliary power supply 25 may be accommodated on a main board of the controller 7 in order to supply the volatile memory 16 and/or the persistent storage 17 with auxiliary power. In particular, the auxiliary power supply 25 may be performed in the form of a supercapacitor, an accumulator and/or a battery. The power capacity/energy capacity of the main power supply 24 can be many times greater, for example at least 10 times or 50 times greater, than the power capacity/energy capacity of the auxiliary power supply 25.

The processor 15 monitors changes in the electrical power supplied by the main power supply 24. In the event of a sudden power failure, such as when the power source external to the controller 7 is disconnected from the main power supply 24 or the main power supply 24 degrades or fails for some other reason, and the processor 15 determines that the electrical power supplied by the main power supply 24 to one or more of the components of the controller 7 has fallen below a threshold value, such as 0.8 or 0.75 of an operating power of the main power supply 24, the processor 15 causes the auxiliary power supply 25 to be disconnected from the main power supply 24. 0.8 or 0.75 of an operating power of the main power supply 24, the processor 15 causes the auxiliary power supply 25 to take over a remaining supply power for a shutdown operation of the controller 7. The shutdown operation comprises supplying power to at least the processor 15, the volatile memory 16 and/or the persistent storage 17 with electrical power for the time of the shutdown operation. During the shutdown process, the data based on the input signal/output signal that is currently in the volatile memory 16 and/or the data based on the input signal/output signal that is currently being processed in the processor 15, for example in the register/cache of the processor 15, is transferred from the volatile memory 16 and/or the processor 15 to a meta area of the persistent storage 17. For this purpose, the meta area of the persistent storage 17 can be kept available especially for the shutdown process.

The processor 15 loads the data based on the input signal/output signal from the meta area of the persistent storage 17 in the case of a startup operation of the controller 7, in which the main power supply 24 again provides the operating power, in order to enable faster data processing. After the startup process, the meta area of the persistent storage or successively during the startup process can be released.

FIG. 4 shows a control block diagram for degradation diagnosis. The block diagram illustrates the method presented herein. In order to diagnose the degradation of the power electronic module 2, the periodic conduction losses in the semiconductor device are excited. In the example of the MOSFET, these conduction losses can be calculated as Pₗₒₛₛ=_{v(ds)}*i_{ds}=_{R(DS,on)}(v_{GS}, Tⱼ)*i_{(ds)}_{²}, where v_{ds} is the forward voltage (drain-source voltage), R_{DS,on} is the ON-resistance and i_{ds} is the drain-source current of the MOSFET. In order to generate periodic conduction losses within the device, the ON-resistance R_{DS,on} is manipulated in the on-state. The ON-resistance R_{DS,on} of a MOSFET depends on the gate-source voltage v_{GS} and the junction temperature Tⱼ. The modulation of the ON-resistance R_{DS,on} can therefore be achieved by superimposing a periodic, preferably sinusoidal or rectangular, gate-source AC voltage v_{ac} on the gate-source DC voltage V₀.

This periodic excitation of the ON-resistance R_{DS,on} leads to a periodic (small) signal modulation of the conduction losses P_{cond} and the drain-source voltage v_{ds}, both of which have a constant phase delay of 180° with respect to vas for low frequencies. The thermal impedance Zₜₕ(jω), which is represented in FIG. 4 in simplified form as thermal resistance Rₜₕ and thermal capacity Cₜₕ, describes how the junction temperature Tⱼ responds to the periodic loss excitation in magnitude and phase. In addition to the gate-source voltage v_{GS} affecting the ON-resistance R_{DS,on}, the junction temperature Tⱼ that occurs in response to the loss excitation causes an additional phase shift in the drain-source voltage v_{ds}. Consequently, the phase shift of the drain-source voltage v_{ds} changes when a degradation affects the phase of the thermal impedance Zₜₕ(jω), e.g. due to changes in the total Rₜₕ. Therefore, changes in the phase shift between gate-source voltage v_{GS} and drain-source voltage v_{ds} indicate changes in the phase of thermal impedance ∠_{Z(th)}(jω) that occur when the characteristics of the thermal heat dissipation path change due to degradation modes or changes in convection conditions. Therefore, the method proposed herein is able to detect different modes of degradation separately by focusing on the phase delay at different frequencies as the different degradation modes leave traces at bandwidths that can be clearly determined.

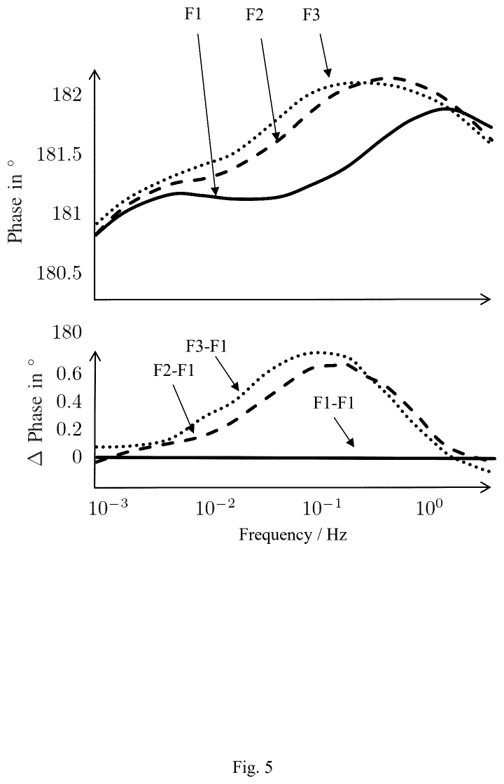

FIG. 5 shows frequency-resolved phase diagrams with corresponding phase responses F1-F3 for a better understanding of the method. Here, the three phase responses F1-F3 at the top of FIG. 5 differ in that small changes in the thermal path below the semiconductor device 3 have been artificially introduced. In this example, the thermally conductive layer to the heat sink of the power electronic module 2 was removed a little F2 and all of F3 in order to map degradation effects. Such degradation effects below the power electronic module 2 can be recognized by the phase of the thermal impedance in the millihertz range. Frequencies of the (low) signal in the range from 1 mHz to 5 Hz are particularly suitable for this purpose.

At this point, it should be noted that all the parts described above are claimed to be essential to the invention when viewed individually and in any combination, in particular the details shown in the drawings. Modifications thereof are familiar to the skilled person.

REFERENCE LIST

| | |
|---|---|
| 1 | Power electronic system |
| 2 | Power electronic module |
| 3 | Semiconductor device |
| 4 | Control terminal |
| 5 | Drain terminal |
| 6 | Source terminal |
| 7 | Controller |
| 8 | DAC |
| 9 | First instrumentation amplifier |
| 10 | first anti-aliasing filter |
| 11 | first ADC |
| 12 | second instrumentation amplifier |
| 13 | second anti-aliasing filter |
| 14 | second ADC |
| 15 | processor |
| 16 | Volatile memory |
| 17 | Persistent storage |
| 18 | NVM Controller |
| 19 | NVM |
| 20 | Bus |
| 21 | Arbiter |
| 22 | Communication interface |
| 23 | Power terminal |
| 24 | Main power supply |
| 25 | Auxiliary power supply |
| F1 | Phase response without degradation |
| F2 | Phase response with 1st type degradation |
| F3 | Phase response with 2nd type degradation |
| V₀ | Gate-source DC voltage |
| v_{ac} | Gate-source AC voltage |
| v_{GS} | Gate-source voltage |
| R_{DS, on} | ON-resistance |
| Tⱼ | junction temperature |
| v_{ds} | Drain-source voltage |
| i_{ds} | Drain-source current |
| P_{cond} | Power losses |
| Cₜₕ | thermal capacity |
| Rₜₕ | thermal resistance |

1. A method for degradation diagnosis of a power electronic module having a semiconductor device, the method comprising:
providing an input signal of the power electronic module including a large signal component provided for switching on the semiconductor device;
recording an output signal of the power electronic module based on the input signal to enable a degradation diagnosis of the power electronic module;
wherein the input signal includes a periodic signal component.

2. The method according to claim 1, wherein the periodic signal component is a chirp that is provided by changing a frequency of the periodic signal component over time.

3. The method according to claim 2, wherein the chirp has a frequency range between 0.1 mHz and 100 Hz.

4. The method according to claim 3, wherein the large signal component of the input signal ensures a switch-on state of the semiconductor device over a duration of the chirp.

5. The method according to claim 1, wherein determining a degradation of one or more components associated with the power electronic module by frequency-resolved comparison of a phase of the output signal with a phase of the input signal.

6. The method according to claim 5, wherein the degradation of components associated with the power electronic module is determined by phase differences between the output signal and the input signal in corresponding frequency subranges associable with the plurality of components associated with the power electronic module, and that the frequency subranges differ from component to component of the components associated with the power electronic module.

7. A computer program, wherein the computer program comprises instructions which, when the computer program is executed by a computer or by a controller, cause the computer or the controller to perform or initiate the method according to claim 1 or at least one step thereof.

8. A data carrier, wherein the computer program according to claim 7 is stored on the data carrier.

9. A controller for degradation diagnosis of a power electronic module with a semiconductor device, the controller being adapted to:
provide an input signal of the power electronic module including a large signal component provided for switching on the semiconductor device;
record an output signal of the power electronic module based on the input signal to enable a degradation diagnosis of the power electronic module;
wherein the input signal includes a periodic signal component.

10. A power electronic module with a semiconductor device, wherein the power electronic module is adapted to:
receive an input signal of the power electronic module including a large signal component provided for switching on the semiconductor device;
deliver an output signal of the power electronic module based on the input signal to enable a degradation diagnosis of the power electronic module;
wherein the input signal includes a periodic signal component.
